(19) United States
(12) Patent Application Publication
(10) Pub. No.: US 2026/0080944 A1
(43) Pub. Date: Mar. 19, 2026

(54) MEMORY DEVICES, OPERATION METHODS OF MEMORY DEVICES, AND MEMORY SYSTEMS

(71) Applicant: Yangtze Memory Technologies Co., Ltd., Wuhan (CN)

(72) Inventors: Zhipeng Dong, Wuhan (CN); Xufeng Zhou, Wuhan (CN); Ke Ke, Wuhan (CN)

(21) Appl. No.: 19/052,134

(22) Filed: Feb. 12, 2025

(30) Foreign Application Priority Data
Sep. 18, 2024 (CN) 2024113037671

(51) Int. Cl. G11C 16/10; G11C 16/08; G11C 16/30

(52) U.S. Cl. CPC G11C 16/102; G11C 16/08; G11C 16/30

(57) ABSTRACT

Implementations of the present disclosure provide a memory device and its operation method and memory system, wherein the memory device includes: a memory cell array; a plurality of word lines; a peripheral circuit coupled to the memory cell array through the plurality of word lines, wherein the peripheral circuit is configured to: in a first stage of a programming operation, apply a first voltage to a first word line and a second word line of the plurality of word lines; in a second stage of the programming operation, apply a second voltage greater than the first voltage to the first word line and the second word line; wherein the first word line and the second word line are located on a same side of a selected word line of the plurality of word lines.

### CROSS-REFERENCE TO RELATED APPLICATIONS

This application claims priority to and the benefit of Chinese Patent Application 202411303767.1, filed on Sep. 18, 2024, which is hereby incorporated by reference in its entirety.

### TECHNICAL FIELD

The implementations of the present disclosure relate to the field of semiconductor technology, and more particularly to a memory devices, operating methods of memory devices, and memory systems.

### BACKGROUND

Memory devices are storage devices configured to store information in modern information technology. As a typical non-volatile semiconductor memory, NAND (Not-And) flash memory has become a mainstream product in the storage market due to its high storage density, controllable production cost, suitable programming and erasing speed and retention characteristics.

### BRIEF DESCRIPTION OF THE DRAWINGS

FIG. 1 is a schematic diagram of an example system having a memory system according to an implementation of the present disclosure.

FIG. 2A is a schematic diagram of an example memory card having a memory system according to an implementation of the present disclosure.

FIG. 2B is a schematic diagram of an example solid-state drive having a memory system according to an implementation of the present disclosure.

FIG. 3A is a schematic diagram of the distribution of memory cells of a three-dimensional NAND type memory according to an implementation of the present disclosure.

FIG. 3B is a schematic diagram of an example memory device including a peripheral circuit according to an implementation of the present disclosure.

FIG. 4 is a cross-sectional schematic diagram of a memory cell array including a NAND memory string according to an implementation of the present disclosure.

FIG. 5 is a schematic diagram of an example memory device including a memory cell array and a peripheral circuit according to an implementation of the present disclosure.

FIG. 6 is the first schematic diagram of voltage timing corresponding to each of elements at different stages of a programming cycle according to an implementation of the present disclosure.

FIG. 7 is a schematic diagram of a cross-sectional view of a memory string provided in an implementation of the present application.

FIG. 8 is the second schematic diagram of voltage timing corresponding to each elements at different stages of a programming cycle according to an implementation of the present disclosure.

FIG. 9 is a flow chart of a method of operating a memory system provided in an implementation of the present disclosure.

### DETAILED DESCRIPTION

The following will combine the implementations of the present disclosure and the accompanying drawings to clearly and completely describe the technical solutions in the implementations of the present disclosure. Obviously, the described implementations are only part of the implementations of the present disclosure, not all of the implementations. Based on the implementations in the present disclosure, all other implementations obtained by ordinary technicians in the field without creative work are within the scope of protection of the present disclosure.

In the following description, a large number of details are given to provide a more thorough understanding of the present disclosure. However, it is obvious to those skilled in the art that the present disclosure can be implemented without one or more of these details. In other examples, in order to avoid confusion with the present disclosure, some technical features known in the art are not described; that is, all features of the actual implementations are not described here, and the known functions and structures are not described in detail.

In the drawings, for clarity, the sizes of layers, regions, and elements and their relative sizes may be exaggerated. The same figure marks represent the same elements throughout.

It should be understood that when an element or layer is referred to as “on”, “adjacent to”, “connected to” or “coupled to” other elements or layers, it can be directly on, adjacent to, connected to or coupled to other elements or layers, or there can be intervening elements or layers. In contrast, when an element is referred to as being “directly on”, “directly adjacent to”, “directly connected to” or “directly coupled to” another element or layer, there are no intervening elements or layers. It should be understood that although the terms first, second, third, etc. may be used to describe various elements, components, regions, layers and/or parts, these elements, components, regions, layers and/or parts should not be limited by these terms. These terms are only used to distinguish one element, component, region, layer or part from another element, component, region, layer or part. Therefore, without departing from the teachings of the present disclosure, the first element, component, region, layer or part discussed below may be represented as a second element, component, region, layer or part. When the second element, component, region, layer or part is discussed, it does not indicate that the present disclosure necessarily has a first element, component, region, layer or part.

Spatial relationship terms such as “under”, “below” , “underneath” , “beneath”, “on top of”, “above”, etc., may be used herein for the convenience of description to describe the relationship between an element or feature shown in the figure and other elements or features. It should be understood that the spatial relationship terms are intended to include different orientations of the device in use and operation in addition to the orientation shown in the figures. For example, if the device in the figure is turned over, then the elements or features described as “below other elements” or “beneath” or “under” will be oriented “above” other elements or features. Therefore, the example terms “below” and “under” can include both the above and below orientations. The device can be oriented otherwise (rotated 90 degrees or other orientations) and the spatial descriptors used herein are interpreted accordingly.

The terms used herein are intended only to describe specific implementations and are not intended to be limiting of the present disclosure. When used herein, the singular forms “a”, “an”, and “said/the” are also intended to include the plural forms unless the context clearly indicates otherwise. It should also be understood that the terms “comprising” and/or “including”, when used in this specification, determine the presence of the features, integers, steps, operations, elements and/or parts, but do not exclude the presence or addition of one or more other features, integers, steps, operations, elements, parts and/or groups. When used herein, the term “and/or” includes any and all combinations of the relevant listed items.

In order to thoroughly understand the present disclosure, detailed steps and detailed structures will be presented in the following description to illustrate the technical solution of the present disclosure. The preferred implementations of the present disclosure are described in detail as follows, however, in addition to these detailed descriptions, the present disclosure may also have other implementations.

In view of the increasing requirements for memory devices, it is desirable to improve programming efficiency.

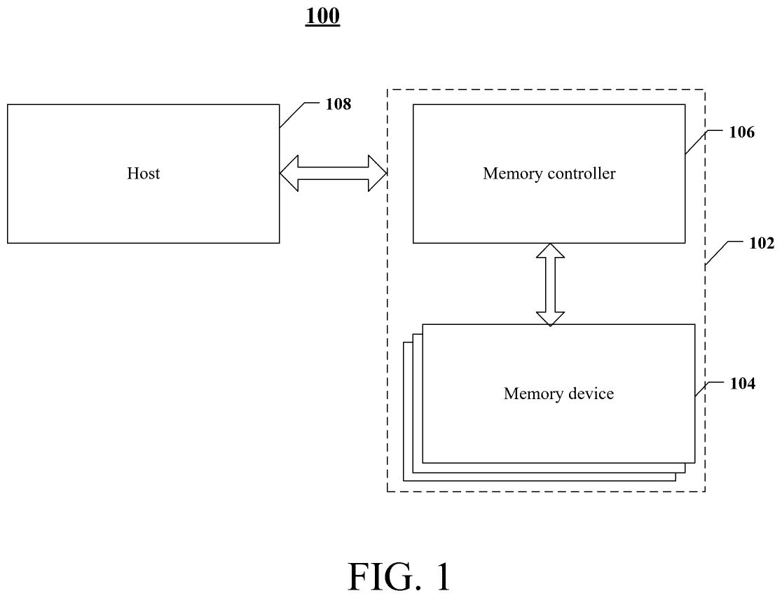

FIG. 1 is a block diagram of an example system 100 having a memory in an implementation of the present disclosure. The system 100 may be a mobile phone, a desktop computer, a laptop computer, a tablet computer, a vehicle computer, a game console, a printer, a positioning device, a wearable electronic device, a smart sensor, a virtual reality (VR) device, an augmented reality (AR) device, or any other suitable electronic device having a storage therein. As shown in FIG. 1, the system 100 may include a host 108 and a memory system 102, the memory system 102 having one or more memories 104 and a memory controller 106. The host 108 may be a processor (e.g., a central processing unit (CPU)) or a system on chip (SoC) (e.g., an application processor (AP)) of an electronic device. The host 108 may be configured to send data to or receive data from the memory 104. The host 108 includes a host controller and a second interface for coupling with the memory controller 106, that is, the second interface can also be an interface for the host to communicate with the memory controller.

In some implementations, the memory controller 106 is coupled to the memory 104 and the host 108, and is configured to control the memory 104. The memory controller 106 can manage data stored in the memory 104 and communicate with the host 108. In some implementations, the memory controller 106 is designed to operate in a low duty cycle environment, such as a secure digital (SD) card, a compact flash (CF) card, a universal serial bus (USB) flash drive, or other media used in electronic devices such as personal computers, digital cameras, mobile phones, etc. In some implementations, the memory controller 106 is designed to operate in a high duty cycle environment SSD or embedded multimedia card (eMMC), which is used as a data storage for mobile devices such as smart phones, tablet computers, laptop computers, etc. and enterprise storage arrays.

The memory controller 106 may be configured to control operations of the memory 104, such as read, erase, and program operations. The memory controller 106 may also be configured to manage various functions regarding data stored or to be stored in the memory 104, including but not limited to bad block management, garbage collection, logical to physical address translation, wear leveling, etc. In some implementations, the memory controller 106 is also configured to process error correction codes (ECC) regarding data read from or written to the memory 104. The memory controller 106 may also perform any other suitable functions, such as formatting the memory 104. The memory controller 106 may communicate with an external device (e.g., a host 108) according to a communication protocol. For example, the memory controller 106 can communicate with an external device through at least one of various interface protocols, such as USB protocol, MMC protocol, peripheral component interconnect (PCI) protocol, PCI Express (PCI-E) protocol, Advanced Technology Attachment (ATA) protocol, Serial ATA protocol, Parallel ATA protocol, Small Computer System Interface (SCSI) protocol, Enhanced Small Disk Interface (ESDI) protocol, Integrated Drive Electronics (IDE) protocol, Firewire protocol, etc. These interfaces can also be referred to as first interfaces (also known as front-end interfaces). The first interface here is an interface coupled to the second interface of the aforementioned host. In some implementations, the memory controller 106 interacts with the memory 104 for commands/data through multiple configured channels. These channels are also referred to as back-end interfaces.

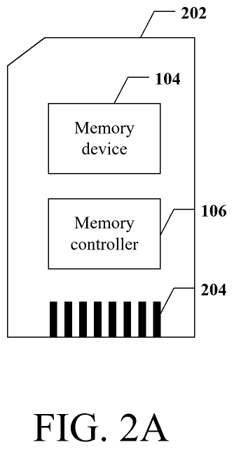

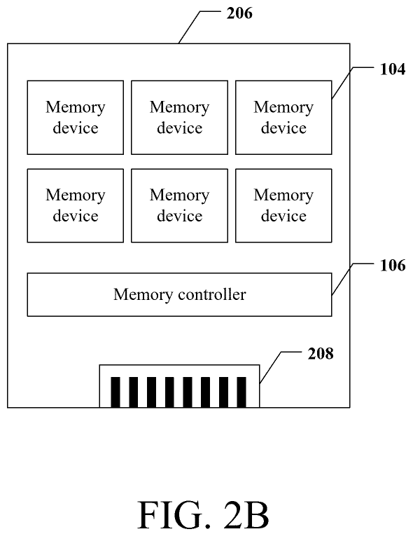

The memory controller 106 and one or more memories 104 can be integrated into various types of storage devices, for example, included in the same package (e.g., Universal Flash Storage (UFS) package or eMMC package). That is, the memory system 102 can be implemented and packaged into different types of end electronic products. In one example as shown in FIG. 2A, the memory controller 106 and the single memory 104 may be integrated into a memory card 202. The memory card 202 may include a PC card (PCMCIA, Personal Computer Memory Card International Association), a CF card, a Smart Media (SM) card, a memory stick, a multimedia card (MMC, RS-MMC, MMCmicro), an SD card (SD, miniSD, microSD, SDHC), UFS, etc. The memory card 202 may also include a memory card connector 204 that couples the memory card 202 with a host (e.g., the host 108 in FIG. 1). In another example as shown in FIG. 2B, the memory controller 106 and the plurality of memories 104 may be integrated into an SSD 206. The SSD 206 may also include an SSD connector 208 that couples the SSD 206 with a host (e.g., the host 108 in FIG. 1). In some implementations, at least one of the storage capacity or operating speed of the SSD 206 is greater than at least one of the storage capacity or operating speed of the memory card 202.

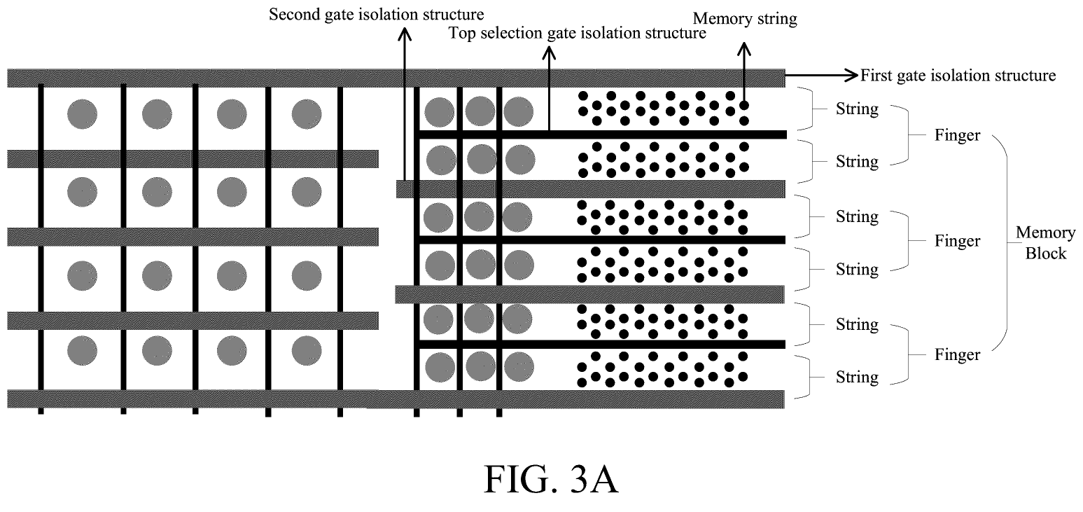

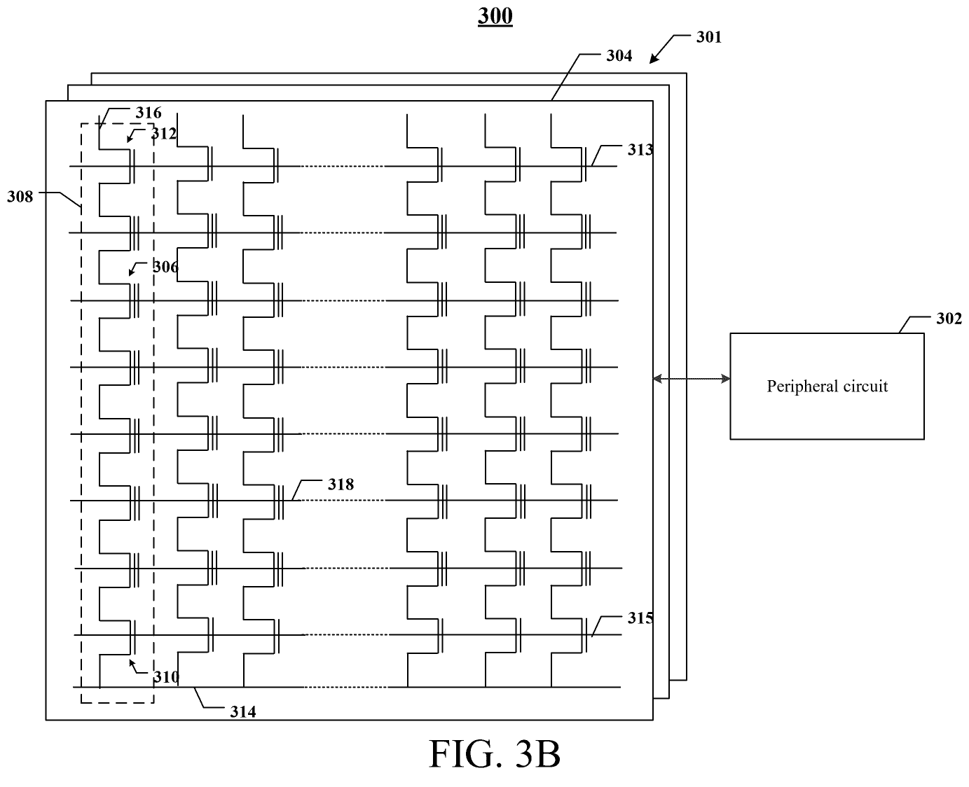

FIG. 3A is a schematic diagram of the structure of a memory cell array of a three-dimensional NAND memory in an implementation of the present disclosure. As shown in FIG. 3A, the memory cell array of the three-dimensional NAND memory is composed of several parallel and staggered rows of memory cells parallel to the gate isolation structure. Every two rows of memory cell rows are separated by a gate isolation structure and an top selection gate isolation structure, and each memory cell row includes multiple memory strings. The gate isolation structure may include a first gate isolation structure and a second gate isolation structure. The first gate isolation structure divides the memory cell array into multiple blocks. The multiple second gate isolation structures may divide the block into multiple fingers. The top selection gate isolation structure provided in the middle of each fingers may divide the finger into two parts, thereby dividing the finger into two strings. A block shown in FIG. 3A includes 6 strings. In practical applications, the number of strings in a block is not limited to this.

It should be noted that the number of rows of memory cell rows between the gate isolation structure and the top selection gate isolation structure given in FIG. 3A is only an example demonstration and is not configured to limit the number of memory cell rows contained in a finger of the three-dimensional NAND memory in the present disclosure. In practical applications, the number of memory cell rows contained in a finger can be adjusted according to actual conditions, such as 2, 4, 8, 16, etc.

FIG. 3B is a schematic circuit diagram of an example memory 300 including a peripheral circuit in an implementation of the present disclosure. The memory 300 may be an example of the memory 104 in FIG. 1. The memory 300 may include a memory cell array 301 and a peripheral circuit 302 coupled to the memory cell array 301. The memory cell array 301 is taken as an example of a three-dimensional NAND memory cell array, wherein the memory cell 306 is provided in the form of an array of NAND memory strings 308, each NAND memory string 308 extending vertically above a substrate (not shown). In some implementations, each NAND memory string 308 includes a plurality of memory cells 306 coupled in series and stacked vertically. Each memory cell 306 can hold a continuous analog value, such as a voltage or charge, which depends on the number of electrons trapped in the area of the memory cell 306. Each memory cell 306 can be a floating gate type memory cell including a floating gate transistor, or a charge trapping type memory cell including a charge trapping transistor.

In some implementations, each memory cell 306 is a single level cell (SLC) having two possible memory states and can therefore store one bit of data. For example, a first memory state “0” can correspond to a first voltage range, and a second memory state “1” can correspond to a second voltage range. In some implementations, each memory cell 306 is a multi-level cell (MLC) capable of storing more than a single bit of data in more than four memory states. For example, an MLC can store two bits per cell, three bits per cell (also known as a three-level cell (TLC)), or four bits per cell (also known as a quad-level cell (QLC)). Each MLC can be programmed to take on a range of possible nominal storage values. In one example, if each MLC stores two bits of data, the MLC can be programmed to take one of three possible programming levels from an erased state by writing one of three possible nominal storage values to the cell. A fourth nominal storage value can be configured to the erased state.

As shown in FIG. 3B, each NAND memory string 308 can include a bottom select gate (BSG) 310 at its source end and an top select gate (TSG) 312 at its drain end. The BSG 310 and the TSG 312 can be configured to activate the selected NAND memory string 308 during read and program operations. In some implementations, the sources of the NAND memory strings 308 in the same memory block 304 are coupled by the same source line (SL) 314 (e.g., a common SL). In other words, according to some implementations, all NAND memory strings 308 in the same memory block 304 have an array common source (ACS). According to some implementations, the TSG 312 of each NAND memory string 308 is coupled to a corresponding bit line (BL) 316, and data can be read from or written to the bit line 316 via an output bus (not shown). In some implementations, each NAND memory string 308 is configured to be selected or deselected by applying a select voltage (e.g., higher than the threshold voltage of a transistor having the TSG 312) or a deselect voltage (e.g., 0V) to the corresponding TSG 312 via one or more TSG lines 313 and/or by applying a select voltage (e.g., higher than the threshold voltage of a transistor having the BSG 310) or a deselect voltage (e.g., 0V) to the corresponding BSG 310 via one or more BSG lines 315.

As shown in FIG. 3B, a NAND memory string 308 may be organized into a plurality of memory blocks 304, each of which may have a common source line 314 (e.g., coupled to ground). In some implementations, each memory block 304 is a basic data unit for an erase operation, e.g., all memory cells 306 on the same memory block 304 are erased simultaneously. To erase the memory cells 306 in a selected memory block, the source lines 314 coupled to the selected memory block and the unselected memory blocks in the same plane as the selected memory block may be biased with an erase voltage (Vers) (e.g., a high positive voltage (e.g., 20V or higher)). It should be understood that in some examples, the erase operation may be performed at a half-memory block level, at a quarter-memory block level, or at a level having any suitable number of memory blocks or any suitable fraction of memory blocks. The memory cells 306 of adjacent NAND memory strings 308 may be coupled by word lines 318, which select which row of memory cells 306 is affected by read and program operations.

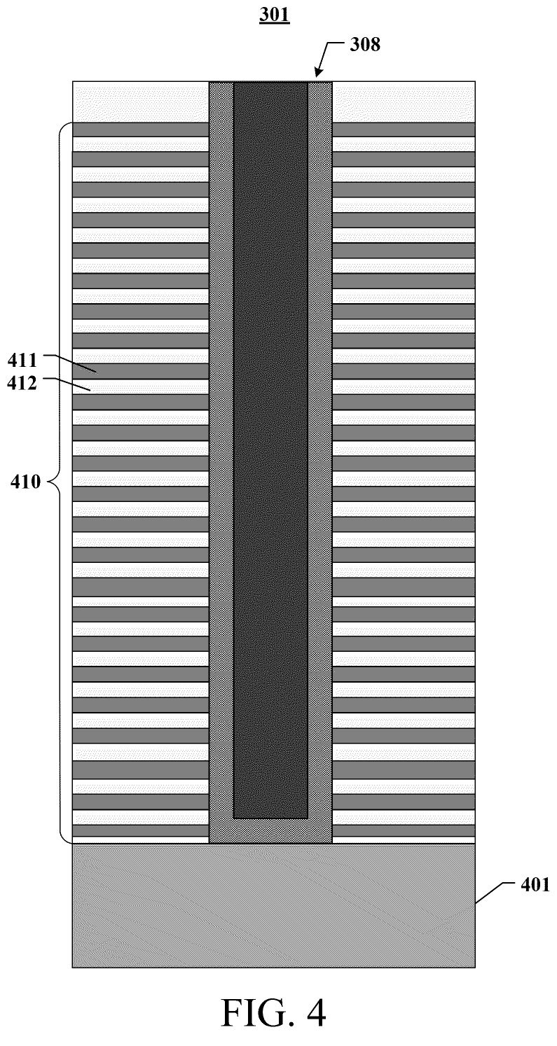

FIG. 4 is a cross-sectional schematic diagram of an example memory cell array 301 including a NAND memory string 308 according to an implementation of the present disclosure. As shown in FIG. 4, the NAND memory string 308 may include a stacked structure 410, which includes a plurality of gate layers 411 and a plurality of insulating layers 412 alternately stacked in sequence, and a memory string 308 vertically penetrating the gate layer 411 and the insulating layer 412. The gate layer 411 and the insulating layer 412 may be alternately stacked, and two adjacent gate layers 411 are separated by a layer of insulating layer 412. The number of pairs of gate layers 411 and insulating layers 412 in the stacked structure 410 may determine the number of memory cells included in the memory cell array 301.

The constituent material of the gate layer 411 may include a conductive material. The conductive material includes, but is not limited to, tungsten (W), cobalt (Co), copper (Cu), aluminum (Al), polysilicon, doped silicon, silicide, or any combination thereof. In some implementations, each gate layer 411 includes a metal layer, for example, a tungsten layer. In some implementations, each gate layer 411 includes a doped polysilicon layer. Each gate layer 411 may include a control gate surrounding a memory cell. The gate layer 411 at the top of the stacked structure 410 may extend laterally as an top selection gate line, the gate layer 411 at the bottom of the stacked structure 410 may extend laterally as a bottom selection gate line, and the gate layer 411 extending laterally between the top selection gate line and the bottom selection gate line may serve as a word line layer.

In some implementations, the stacked structure 410 may be disposed on the semiconductor layer 401. The semiconductor layer 401 may include silicon (e.g., single crystal silicon), silicon germanium (SiGe), gallium arsenide (GaAs), germanium (Ge), silicon on insulator (SOI), germanium on insulator (GOI), or any other suitable material.

In some implementations, the NAND memory string 308 includes a channel structure extending vertically through the stacked structure 410. In some implementations, the channel structure includes a channel hole filled with (one or more) semiconductor materials (e.g., as a semiconductor channel) and (one or more) dielectric materials (e.g., as a memory film). In some implementations, the semiconductor channel includes silicon, such as polysilicon. In some implementations, the memory film is a composite dielectric layer including a tunneling layer, a storage layer (also referred to as a “charge trapping/storage layer”), and a barrier layer. The channel structure may have a cylindrical shape (e.g., a column shape). According to some implementations, the semiconductor channel, the tunneling layer, the storage layer, and the barrier layer are arranged radially in this order from the center of the column toward the outer surface of the column. The tunneling layer may include silicon oxide, silicon oxynitride, or any combination thereof. The storage layer may include silicon nitride, silicon oxynitride, or any combination thereof. The barrier layer may include silicon oxide, silicon oxynitride, a high dielectric constant (high-k) dielectric, or any combination thereof. In one example, the memory film may include a composite layer of silicon oxide/silicon oxynitride/silicon oxide (ONO).

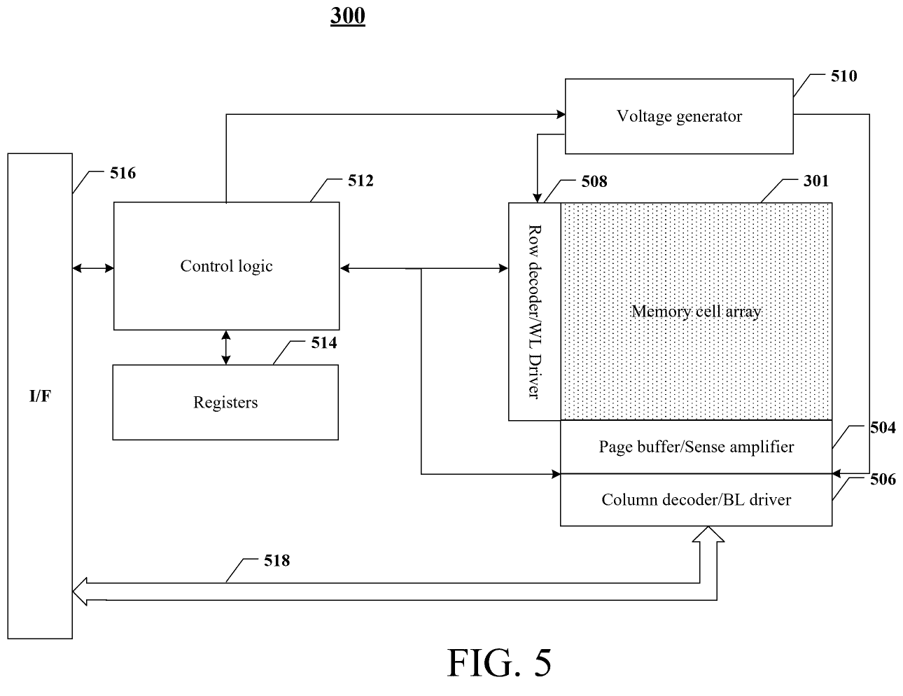

Referring back to FIG. 3B, the peripheral circuit 302 may be coupled to the memory cell array 301 via the bit lines 316, the word lines 318, the source lines 314, the BSG lines 315, and the TSG lines 313. The peripheral circuit 302 may include any suitable analog, digital, and mixed signal circuits for facilitating the operation of the memory cell array 301 by applying at least one of a voltage signal or a current signal to each selected memory cell 306 and sensing at least one of a voltage signal or a current signal from each target memory cell 306 via the bit lines 316, the word lines 318, the source lines 314, the BSG lines 315, and the TSG lines 313. The peripheral circuit 302 may include various types of peripheral circuits formed using metal-oxide-semiconductor (MOS) technology. FIG. 5 is a schematic diagram of an example memory device including a memory cell array and peripheral circuits according to an implementation of the present disclosure, wherein the peripheral circuit 302 includes a page buffer/sense amplifier 504, a column decoder/bit line driver 506, a row decoder/word line driver 508, a voltage generator 510, a control logic 512, a register 514, an interface 516, and a data bus 518. It should be understood that in some examples, additional peripheral circuits not shown in FIG. 5 may also be included.

The control logic 512 may be coupled to each peripheral circuit described above and configured to control the operation of each peripheral circuit. The register 514 may be coupled to the control logic 512 and include a status register, a command register, and an address register for storing status information, a command operation code (OP code), and a command address for controlling the operation of each peripheral circuit. The interface 516 may be coupled to the control logic 512 and act as a control buffer to buffer control commands received from a host (not shown) and relay them to the control logic 512, and to buffer status information received from the control logic 512 and relay them to the host. The interface 516 may also be coupled to the column decoder/bit line driver 506 via the data bus 518, and act as a data I/O interface and a data buffer to buffer data and relay it to or from the memory cell array 301. That is, the interface 516 here is an interface coupled to the back-end interface of the aforementioned memory controller, that is, the interface 516 may also be an interface for the memory to communicate with the memory controller.

In some implementations, the page buffer/sense amplifier 504 may be configured to read data from the memory cell array 301 and program (write) data to the memory cell array 301 according to a control signal from the control logic 512. In one example, the page buffer/sense amplifier 504 may store programming data (write data) to be programmed into the memory cell 306 of the memory cell array 301. In another example, the page buffer/sense amplifier 504 may perform a program verification operation to ensure that the data has been correctly programmed into the memory cell 306 coupled to the selected word line 318. The column decoder/bit line driver 506 may be configured to be controlled by the control logic 512 and select one or more NAND memory strings 308 by applying a bit line voltage generated from the voltage generator 510.

The row decoder/word line driver 508 may be configured to be controlled by the control logic 512 and select/deselect a memory block 304 of the memory cell array 301 and select/deselect a word line 318 of the memory block 304. The row decoder/word line driver 508 may also be configured to drive the word line 318 using the word line voltage generated from the voltage generator 510. In some implementations, the row decoder/word line driver 508 may also select/deselect and drive the BSG line 315 and the TSG line 313. As described in detail below, the row decoder/word line driver 508 is configured to perform a programming operation on the memory cell 306 coupled to the (one or more) selected word line(s) 318. The voltage generator 510 can be configured to be controlled by the control logic 512, and generate word line voltages (e.g., read voltage Vread, programming voltage Vpgm, pass voltage Vpass, channel boosting voltage, verification voltage Vvrf, etc.), bit line voltages, and source line voltages to be supplied to the memory cell array 301.

In some implementations, the programming operation may include multiple stages. For example, the programming operation may include a first stage, a second stage, and a recovery stage. In the first stage, a channel boosting voltage may be applied to the selected word line; in the second stage, a target programming voltage for each programming may be applied to the selected word line; in the recovery stage, the voltage may be dropped to the corresponding voltage, such as Vcc, Vdd, for both the non-selected word line and the selected word line. In the recovery stage, the voltage may be dropped to the corresponding voltage by one or more step-by-step steps, such as first dropping to an intermediate voltage, and maintaining the intermediate voltage for a period of time, and then dropping to the corresponding voltage.

The present disclosure provides a memory device, which includes: a memory cell array; a plurality of word lines; a peripheral circuit coupled to the memory cell array through the plurality of word lines, and the peripheral circuit is configured to: in the first stage of the programming operation, apply a first voltage to the first word line and the second word line of the plurality of word lines; in the second stage of the programming operation, apply a second voltage greater than the first voltage to the first word line and the second word line; wherein the first word line and the second word line are located on the same side of a selected word line of the plurality of word lines.

In the present disclosure, the voltages on the first word line and the second word line are raised in two steps to increase the raising speed of the voltage on the selected word line, thereby reducing the pulse width of the target programming voltage, thereby reducing the programming time.

In some implementations, the selected word line can be any word line of the plurality of word lines in the memory cell array. The first word line and the second word line are unselected word lines, and the first word line and the second word line are located on the same side of the selected word line. The second voltage can be a target pass voltage (Vpass_target), and the target pass voltage can be applied to the unselected word line to turn on the unselected memory cell connected to the unselected word line. The first voltage may be an intermediate voltage (Vpass_middle) less than the target pass voltage (Vpass_target).

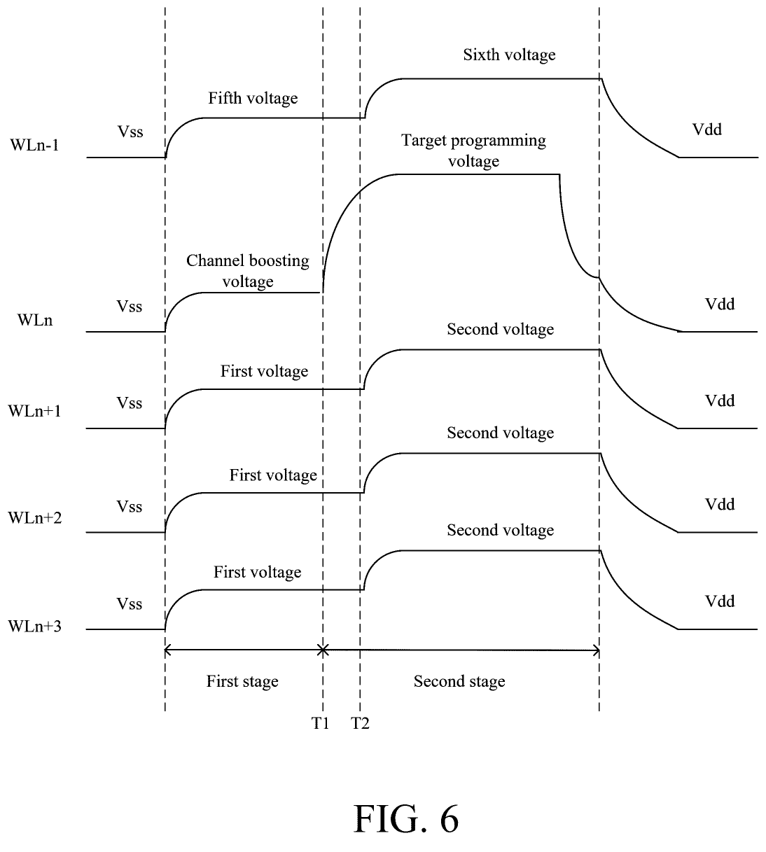

FIG. 6 is a first schematic diagram of the voltage timing corresponding to each of elements at different stages of the programming cycle in an implementation of the present disclosure. As shown in FIG. 6, the selected word line is WLn, the first word line is WLn+1, and the second word line is WLn+2. In the first stage, WLn+1 and WLn+2 may be raised from Vss to the first voltage. In the second stage, WLn+1 and WLn+2 may continue to be raised from the first voltage to the second voltage.

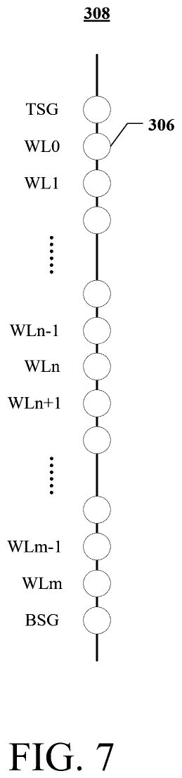

FIG. 7 is a cross-sectional schematic diagram of a memory string provided in an implementation of the present application. It should be noted that FIG. 7 is illustrated by taking reverse programming as an example. As shown in FIG. 7, each memory string 308 includes a plurality of memory cells 306 coupled in series and stacked vertically. The memory string 308 also includes at least one field effect transistor (e.g., MOSFET) at each end, which is controlled by BSG and TSG, respectively. The memory cell 306 may be controlled by a control gate, wherein the control gate may be connected to the word line. TSG can be connected to the bit line, and BSG can be connected to the source line. Here, in FIG. 7, the word lines to which the multiple memory cells 306 included in the memory string 308 are sequentially connected are exemplified as WL0, WL2, . . . WLn, . . . WLm. In some implementations, the programming operation includes programming in an order starting from the word line adjacent to the bit line (such as WL0) to the word line adjacent to the source line (such as WLm) in sequence (also called reverse programming).

In other implementations, the programming operation includes programming in an order starting from the word line adjacent to the source line to the word line adjacent to the bit line in sequence (also called forward programming).

In some implementations, the memory cells connected to the first word line and the second word line are in an unprogrammed state. In combination with FIG. 6 and FIG. 7, the programming operation is reverse programming, and the memory cells connected to WLn+1 and WLn+2 are in an unprogrammed state.

It should be noted that the implementation of the present disclosure is described by taking the programming operation as reverse programming as an example.

In some implementations, the pass voltage Vpass can be generated by a first voltage generator. The first voltage generator belongs to the aforementioned voltage generator 510, and the first voltage generator is configured to generate a first voltage in the first stage and a second voltage in the second stage, so as to be applied to the first word line and the second word line.

When applying the pass voltage Vpass, the implementation of the present disclosure first applies an intermediate voltage, e.g., the first voltage, to the unselected word line, and then applies the target pass voltage to the unselected word line, so that the unselected word line is boosted from the intermediate voltage to the target pass voltage. In other words, in the implementation of the present disclosure, the voltages on the first word line and the second word line are raised to the target pass voltage in two steps.

Because there is a coupling capacitor between the selected word line and the unselected word line. Therefore, when the pass voltage Vpass is applied to the unselected word line, the coupling capacitor can cause the voltage of the selected word line to be raised. In this way, the timing of the capacitive coupling between the selected word line and the unselected word line can be controlled by controlling the second step for raising timing of the pass voltage Vpass (e.g., the timing of applying the target pass voltage), so that the capacitive coupling effect can be utilized to increase the voltage raising speed of the selected word line (such as the raising speed of the target programming voltage), thereby reducing the pulse width of the programming voltage Vpgm, thereby reducing the programming time tPROG.

In the disclosed implementation, the peripheral circuit is configured as follows: in the first stage, a first voltage is applied to a third word line of the plurality of word lines; in the second stage, a second voltage is applied to the third word line; wherein the first word line, the second word line and the third word line are located on the same side of the selected word line.

Continuing to refer to FIG. 6, the third word line is WLn+3. In the first stage, WLn+3 may be raised from Vss to the first voltage. In the second stage, WLn+3 may continue to be raised from the first voltage to the second voltage.

In some implementations, the first voltage generator is configured to generate a first voltage in the first stage and a second voltage in the second stage for applying to the first word line, the second word line and the third word line.

In some implementations, the memory cell connected to the third word line is in an unprogrammed state.

In some implementations, the first word line, the second word line and the third word line are adjacent word lines respectively, and the first word line is a word line adjacent to the selected word line.

In an implementation of the present disclosure, the peripheral circuit is configured as follows: in the first stage, a third voltage is applied to a third word line of a plurality of word lines; in the second stage, a fourth voltage greater than the third voltage is applied to the third word line; wherein the first word line, the second word line and the third word line are located on the same side of the selected word line.

In some implementations, the fourth voltage may be a target pass voltage, and the third voltage may be an intermediate voltage less than the target pass voltage.

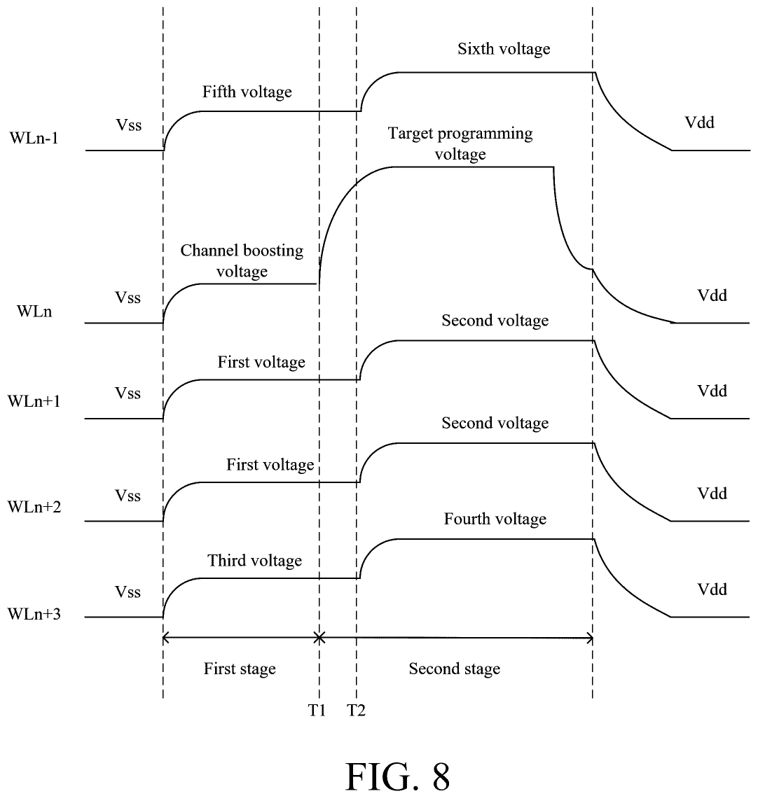

FIG. 8 is a schematic diagram of the voltage timing corresponding to each of elements at different stages of a programming cycle in an implementation of the present disclosure. As shown in FIG. 8, the selected word line is WLn, the first word line is WLn+1, the second word line is WLn+2, and the third word line is WLn+3. In the first stage, WLn+1 and WLn+2 may be raised from Vss to the first voltage, and WLn+3 may be raised from Vss to the third voltage. In the second stage, WLn+1 and WLn+2 may continue to be raised from the first voltage to the second voltage, and WLn+3 may continue to be raised from the third voltage to the fourth voltage.

In some implementations, the third voltage is equal to the first voltage, and the fourth voltage is different from the second voltage.

In some implementations, the first voltage may be in the range of 3V to 5V, and the third voltage may be equal to the first voltage. In an example, the first voltage and the third voltage may be 4V. The second voltage may be in the range of 5V to 11V, and the fourth voltage may be in the range of 5V to 11V. In an example, the second voltage may be greater than the fourth voltage.

In some implementations, when the fourth voltage is different from the second voltage, the third voltage and the fourth voltage may be generated by a second voltage generator. The second voltage generator belongs to the aforementioned voltage generator 510, and the second voltage generator is configured to generate the third voltage in the first stage and the fourth voltage in the second stage for applying to the third word line. In other words, the voltages on the third word line and the voltages on the first word line and the second word line are generated by different voltage generators.

In the implementation of the present disclosure, the peripheral circuit is configured as follows: in the first stage, a fifth voltage is applied to the fourth word line of the plurality of word lines; in the second stage, a sixth voltage greater than the fifth voltage is applied to the fourth word line; wherein the fourth word line is located on a side of the selected word line different from the side of the selected word line on which the first word line and the second word line are located.

In some implementations, the memory cell connected to the fourth word line is in a programmed state.

In some implementations, the fourth word line is a word line adjacent to the selected word line, and the fourth word line and the first word line are located on different sides of the selected word line.

In some implementations, the sixth voltage may be a target pass voltage, and the fifth voltage may be an intermediate voltage less than the target pass voltage.

Continuing to refer to FIG. 6 and FIG. 8, the fourth word line is WLn−1. In the first stage, WLn−1 may be raised from Vss to the fifth voltage. In the second stage, WLn−1 may continue to be raised from the fifth voltage to the sixth voltage.

In some implementations, the first voltage and the fifth voltage are equal, and the second voltage is greater than the sixth voltage.

In some implementations, the fifth voltage may be in the range from 3V to 5V, and the fifth voltage may be equal to the first voltage. In an example, the first voltage, the third voltage, and the fifth voltage may be equal. The sixth voltage may be in the range from 5V to 11V.

In some implementations, the difference between the first voltage and the fifth voltage is less than or equal to 1V.

Since the first word line and the fourth word line are both word lines adjacent to the selected word line, and the fourth word line and the first word line are located on different sides of the selected word line respectively, the difference between the voltages applied on the first word line and the fourth word line needs to be controlled within a certain range (such as within 1V) to avoid the affects to the selected word line.

In some implementations, the fifth voltage may be in the range from 3V to 5V. In an example, the first voltage may be greater than the fifth voltage.

In some implementations, in the same memory string, the greater the distance from the selected word line is, the smaller the target pass voltage applied to the word line is.

In some implementations, multiple target pass voltages including the second voltage, the fourth voltage, and the sixth voltage may be applied to the corresponding word lines. During the programming operation, all word lines in the memory string may be divided into multiple regions. Different target pass voltages may be applied to word lines in different regions to achieve the purpose of individually controlling the target pass voltage. Through this dynamic control of applying different target pass voltages based on the positions of the word lines, the interference to the pass voltage Vpass may be greatly reduced.

In the disclosed implementation, the peripheral circuit is configured to: in the first stage, apply a channel boosting voltage to the selected word line; in the second stage, apply a target programming voltage to the selected word line.

In some implementations, the channel boosting voltage may be in a range from 6V to 11V, and the channel boosting voltage may be greater than the first voltage.

Continuing to refer to FIG. 6 and FIG. 8, in the first stage, WLn may be raised from Vss to the channel boosting voltage. In the second stage, WLn may continue to be raised from the channel boosting voltage to the target programming voltage.

In some implementations, the programming voltage Vpgm may be generated by a third voltage generator. The third voltage generator belongs to the aforementioned voltage generator 510, and the third voltage generator is configured to generate the channel boosting voltage in the first stage and the target programming voltage in the second stage, for applying to the selected word line.

In the disclosed implementation, incremental step pulse programming (ISPP) may be adopted to program the memory device. In particular, when performing a programming operation for the target state, a first programming voltage is first applied to the selected word line, and then a verification operation is performed on the selected memory cell connected to the selected word line to check whether the threshold voltage of each of selected memory cells connected to the selected word line reaches the target threshold voltage. If the number of selected memory cells that have not been programmed to the target threshold voltage is greater than the allowable range, a second programming voltage with a higher voltage is reapplied, and the verification operation is performed again after the second programming voltage is applied. Repeat the above process of applying programming pulses and performing verification operations until the number of selected memory cells that have not been programmed to the target threshold voltage is within the allowable range, and the programming is completed.

When applying the programming voltage, the implementation of the present disclosure first applies a channel boosting voltage to the selected word line, and then applies the target programming voltage to the selected word line, so that the selected word line is boosted from the channel boosting voltage to the target programming voltage, which can effectively achieve voltage buffering to reduce damage to the device.

In some implementations, the time instance for applying the target programming voltage is the same as the time instance for applying the second voltage. In other implementations, the time instance for applying the target programming voltage is different from the time instance for applying the second voltage, for example, a time instance for applying the target programming voltage is earlier than a time instance for applying the second voltage.

Referring back to FIG. 6 and FIG. 8, the second stage includes time instance T1 and time instance T2, at time instance T1, the program voltage is applied to the selected word line WLn, at time instance T2, the second voltage is applied to the first word line WLn+1 and the second word line WLn+2.

In the later stage of programming, as the programming voltage continues to increase, the raising speed of the programming voltage gradually decreases, in other words, when the programming voltage is large, its raising speed is slow. In particular, in the second stage of the programming operation, the raising of the voltage applied to the selected word line can have two slope stages, wherein the slope of the slope stage starting with the channel boosting voltage is greater than the slope of the slope stage ending with the target programming voltage. For example, in the second stage of the programming operation, the selected word line may continue to be raised from the channel boosting voltage (such as 6V) to the target programming voltage (such as 20V), and the period from 6V to 20V includes two slope stages, namely, the slope stage starting with the channel boosting voltage (such as the stage from 6V to 15V) and the slope stage ending with the target programming voltage (such as the stage from 15V to 20V), and the slope of the stage from 6V to 15V is greater than the slope of the stage from 15V to 20V. That is, the voltage raising speed in the stage from 15V to 20V is less than the voltage raising speed in the stage from 6V to 15V. In order to increase the voltage raising speed in the stage from 15V to 20V for the selected word line, the time instance for applying target pass voltage is later than the time instance for applying target programming voltage, so that the capacitive coupling between the selected word line and the unselected word line occurs in the stage from 15V to 20V for the selected word line.

In the implementation of the present disclosure, time instances for the target pass voltage application and the target programming voltage application can be controlled so that the capacitive coupling between the selected word line and the unselected word line occurs in the late stage when the selected word line rises from the channel boosting voltage to the target programming voltage, so as to increase the voltage raising speed of the selected word line. Thereby reducing the pulse width of the programming voltage Vpgm, thereby the programming time tPROG can be reduced.

In some implementations, the time instance for applying the target programming voltage and the time instance for applying the second voltage are separated by 7-10 microseconds. Referring back to FIG. 6 and FIG. 8, the interval between the time instance T1 and the time instance T2 is 7-10 microseconds. The time interval between the time instance T1 and the time instance T2 is related to the voltage rise during the period when the selected word line rises from the channel boosting voltage to the target programming voltage.

In the implementation of the present disclosure, the time interval between the time instance for applying the target programming voltage and the time instance for applying the second voltage can be determined according to the voltage rise during the period when the selected word line rises from the channel boosting voltage to the target programming voltage.

In the implementation of the present disclosure, the peripheral circuit is configured to: in the first stage, apply a fifth voltage to the fifth word line and the sixth word line of the plurality of word lines; wherein the fifth word line is located on the side of the fourth word line away from the selected word line, and the sixth word line is located on the side of the third word line away from the selected word line.

In some implementations, the fifth voltage can be the target pass voltage, and the fifth voltage can be different from the second voltage. The fifth voltage can be in the range from 3V to 11V. In an example, the second voltage can be greater than the fifth voltage.

Referring back to FIG. 6 and FIG. 8, the fifth word line is WLn−2, and the sixth word line is WLn+4. In the first stage, WLn−2 and WLn+4 may be raised from Vss to the fifth voltage. In the second stage, WLn−2 and WLn+4 are maintained at the fifth voltage.

Since the fifth word line and the sixth word line are farther from the selected word line, compared to the first word line to the fourth word line, the fifth word line and the sixth word line have a weaker influence on the selected word line, so the voltages on the fifth word line, the sixth word line and other word lines located on the side of the fifth word line and the sixth word line away from the selected word line are raised to the target pass voltage in one step.

In the implementation of the present disclosure, the timing of the capacitive coupling between the selected word line and the unselected word line is controlled by controlling the second step for raising timing of the pass voltage Vpass (e.g., the timing of applying the target pass voltage), so that the capacitive coupling effect can be utilized to increase the raising speed of the voltage on the selected word line (such as the raising speed of the target programming voltage), thereby reducing the pulse width of the programming voltage Vpgm, thereby reducing the programming time tPROG.

In some implementations, the memory device includes a three-dimensional NAND memory.

However, the memory device in the implementation of the present disclosure is not limited to a three-dimensional NAND memory. In the implementations of the present disclosure, the memory device may be a semiconductor memory, including but not limited to three-dimensional NAND flash memory, vertical NAND flash memory, NOR flash memory, dynamic random access memory (DRAM), ferroelectric random access memory (FRAM), magnetoresistive random access memory (MRAM), phase change random access memory (PCRAM), resistive random access memory (RRAM) or nano random access memory (NRAM), etc.

The implementations of the present disclosure also provide a memory system, the memory system comprising: one or more memory devices as in any of the above implementations; and a memory controller; the memory controller is coupled to the memory device and configured to control the memory device.

Here, the structure and composition of the memory system can refer to the relevant structure and composition of the memory system 102 in FIG. 1, FIG. 2A, and FIG. 2B. For the sake of brevity, it will not be repeated here.

In some implementations, the memory system includes a memory card or a solid state drive.

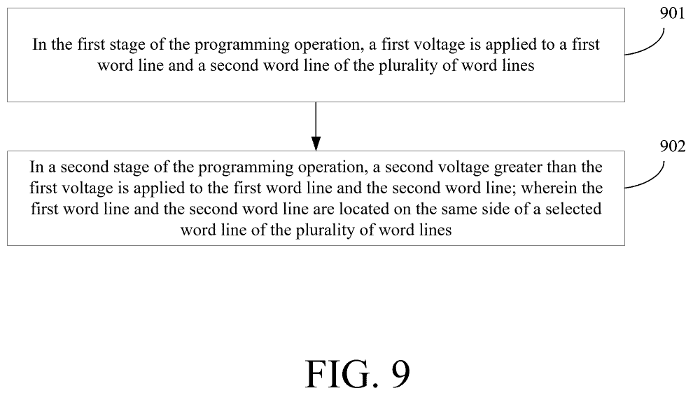

Based on the above-mentioned memory device, the implementation of the present disclosure also provides a method of operating the memory device, as shown in FIG. 9, the method includes:
operation 901: In the first stage of the programming operation, a first voltage is applied to the first word line and the second word line of the plurality of word lines;
operation 902: In the second stage of the programming operation, a second voltage greater than the first voltage is applied to the first word line and the second word line; wherein the first word line and the second word line are located on the same side of the selected word line of the plurality of word lines.

In some implementations, the method further includes: in the first stage, a first voltage is applied to the third word line of the plurality of word lines; in the second stage, a second voltage is applied to the third word line; wherein the first word line, the second word line and the third word line are located on the same side of the selected word line.

In some implementations, the method further includes: in the first stage, a third voltage is applied to the third word line of the plurality of word lines; in the second stage, a fourth voltage greater than the third voltage is applied to the third word line; wherein the first word line, the second word line and the third word line are located on the same side of the selected word line.

In some implementations, the third voltage is equal to the first voltage, and the fourth voltage is different from the second voltage.

In some implementations, the memory cells connected to the first word line, the second word line, and the third word line are in an unprogrammed state.

In some implementations, the method further includes: in the first stage, applying a fifth voltage to a fourth word line of the plurality of word lines; in the second stage, applying a sixth voltage greater than the fifth voltage to the fourth word line; wherein the fourth word line is located on a side of the selected word line different from the side of the selected word line on which the first word line and the second word line are located.

In some implementations, the first voltage and the fifth voltage are equal, and the second voltage is greater than the sixth voltage.

In some implementations, the difference between the first voltage and the fifth voltage is less than or equal to 1V.

In some implementations, the method further includes: in the first stage, applying a channel boosting voltage to the selected word line; in the second stage, applying a target programming voltage to the selected word line.

In some implementations, a time instance for applying the target programming voltage is earlier than a time instance for applying the second voltage.

In some implementations, the method further includes: in the first stage, applying a fifth voltage to the fifth word line and the sixth word line of the plurality of word lines; wherein the fifth word line is located on the side of the fourth word line away from the selected word line, and the sixth word line is located on the side of the third word line away from the selected word line.

Since the contents and structures involved in the description of the memory device in any implementation above can be fully or partially applicable to the operation method of the memory device described here, the contents related or similar thereto are not repeated here.

It should be understood that the “one implementation” or “an implementation” mentioned throughout the specification means that the specific features, structures or characteristics related to the implementation are included in at least one implementation of the present disclosure. Therefore, “in one implementation” or “in an implementation” appearing in various places throughout the specification does not necessarily refer to the same implementation. In addition, these specific features, structures or characteristics can be combined in one or more implementations in any suitable manner. It should be understood that in various implementations of the present disclosure, the size of the sequence number of the above-mentioned processes does not mean the order of execution. The execution order of each process should be determined by its function and internal logic, and should not constitute any limitation on the implementation process of the implementation of the present disclosure. The above-mentioned sequence numbers of the implementations of the present disclosure are only for description and do not represent the advantages and disadvantages of the implementations.

The implementations of the present disclosure provide a memory device and its operation method and memory system.

In a first aspect, the implementations of the present disclosure provide a memory device, the memory device comprising: a memory cell array; a plurality of word lines; a peripheral circuit, coupled to the memory cell array through the plurality of word lines, the peripheral circuit being configured to: apply a first voltage to a first word line and a second word line of the plurality of word lines in a first stage of the programming operation; apply a second voltage greater than the first voltage to the first word line and the second word line in a second stage of the programming operation; wherein the first word line and the second word line are located on a same side of a selected word line of the plurality of word lines.

In an implementation, the peripheral circuit is configured to: apply a first voltage to a third word line of the plurality of word lines in the first stage; apply a second voltage to the third word line in the second stage; wherein the first word line, the second word line, and the third word line are located on a same side of the selected word line.

In an implementation, the peripheral circuit is configured to: apply a third voltage to a third word line of the plurality of word lines in the first stage; apply a fourth voltage greater than the third voltage to the third word line in the second stage; wherein the first word line, the second word line, and the third word line are located on a same side of the selected word line.

In an implementation, the peripheral circuit includes: a control logic and a first voltage generator and a second voltage generator coupled to the control logic; the control logic is configured to: control the first voltage generator to generate the first voltage, control the second voltage generator to generate the third voltage, apply the first voltage to the first word line and the second word line in the first stage, and apply the third voltage to the third word line; control the first voltage generator to generate the second voltage, control the second voltage generator to generate the fourth voltage, apply the second voltage to the first word line and the second word line in the second stage, and apply the fourth voltage to the third word line.

In an implementation, the memory cells connected to the first word line, the second word line and the third word line are in an unprogrammed state.

In an implementation, the peripheral circuit is configured to: apply a fifth voltage to the fourth word line of the plurality of word lines in the first stage; apply a sixth voltage greater than the fifth voltage to the fourth word line in the second stage; wherein the fourth word line is located on a side of the selected word line different from the side of the selected word line on which the first word line and the second word line are located.

In an implementation, the peripheral circuit is configured to: apply a channel boosting voltage to the selected word line in the first stage; apply a target programming voltage to the selected word line in the second stage.

In an implementation, a time instance for applying the target programming voltage is earlier than a time instance for applying the second voltage.

In an implementation, the peripheral circuit is configured to: apply a fifth voltage to the fifth word line and the sixth word line of the plurality of word lines in the first stage; wherein the fifth word line is located on the side of the fourth word line away from the selected word line, and the sixth word line is located on the side of the third word line away from the selected word line.

In an implementation, the memory device further includes: a bit line and a source line; the programming operation includes programming in an order starting from the word line adjacent to the source line to the word line adjacent to the bit line in sequence, or programming in an order starting from the word line adjacent to the bit line to the word line adjacent to the source line in sequence.

In a second aspect, the implementation of the present disclosure provides a memory system, comprising: a memory device as in any one of the first aspects; and a memory controller; the memory controller is coupled to the memory device and configured to control the memory device.

In a third aspect, an implementation of the present disclosure provides a method of operating a memory device, the method comprising: applying a first voltage to a first word line and a second word line of a plurality of word lines in a first stage of a programming operation; applying a second voltage greater than the first voltage to the first word line and the second word line in a second stage of a programming operation; wherein the first word line and the second word line are located on a same side of a selected word line of the plurality of word lines.

In an implementation, the method further comprises: applying a first voltage to a third word line of the plurality of word lines in a first stage; applying a second voltage to the third word line in a second stage; wherein the first word line, the second word line and the third word line are located on a same side of the selected word line.

In an implementation, the method further comprises: applying a third voltage to a third word line of the plurality of word lines in a first stage; applying a fourth voltage greater than the third voltage to the third word line in a second stage; wherein the first word line, the second word line and the third word line are located on a same side of the selected word line.

In an implementation, the memory cells connected to the first word line, the second word line and the third word line are in an unprogrammed state.

In an implementation, the method further includes: applying a fifth voltage to a fourth word line of the plurality of word lines in the first stage; applying a sixth voltage greater than the fifth voltage to the fourth word line in the second stage; wherein the fourth word line is located on a side of the selected word line different from the side of the selected word line on which the first word line and the second word line are located.

In an implementation, the method further includes: applying a channel boosting voltage to the selected word line in the first stage; applying a target programming voltage to the selected word line in the second stage.

In an implementation, a time instance for applying the target programming voltage is earlier than a time instance for applying the second voltage.

In an implementation, the method further includes: applying a fifth voltage to a fifth word line and a sixth word line of the plurality of word lines in the first stage; wherein the fifth word line is located on a side of the fourth word line away from the selected word line, and the sixth word line is located on a side of the third word line away from the selected word line.

The disclosed implementation provides a memory device and an operation method thereof, and a memory system, wherein the memory device comprises: a memory cell array; a plurality of word lines; a peripheral circuit, which is coupled to the memory cell array through the plurality of word lines, and the peripheral circuit is configured to: apply a first voltage to the first word line and the second word line of the plurality of word lines in the first stage of the programming operation; apply a second voltage greater than the first voltage to the first word line and the second word line in the second stage of the programming operation; wherein the first word line and the second word line are located on a same side of a selected word line of the plurality of word lines. In the disclosed implementation, the voltages on the first word line and the second word line are raised in two steps to increase the raising speed of the voltage on the selected word line, thereby reducing the pulse width of the target programming voltage, thereby reducing the programming time.

The above description is only a preferred implementation of the present disclosure, and does not limit the patent scope of the present disclosure. All equivalent structural transformations made by using the contents of the present disclosure and the drawings under the inventive concept of the present disclosure, or directly/indirectly applied in other related technical fields are included in the patent protection scope of the present disclosure.

What is claimed is:

1. A memory device, comprising:
a memory cell array;
a plurality of word lines;
a peripheral circuit coupled to the memory cell array through the plurality of word lines, and configured to:
apply a first voltage to a first word line and a second word line of the plurality of word lines in a first stage of a programming operation; and
apply a second voltage greater than the first voltage to the first word line and the second word line in a second stage of the programming operation;
wherein the first word line and the second word line are located on a same side of a selected word line of the plurality of word lines.

2. The memory device of claim 1, the peripheral circuit is further configured to:
apply the first voltage to a third word line of the plurality of word lines in the first stage; and
apply the second voltage to the third word line in the second stage;
wherein the first word line, the second word line and the third word line are located on a same side of the selected word line.

3. The memory device of claim 1, the peripheral circuit is further configured to:
apply a third voltage to a third word line of the plurality of word lines in the first stage; and
apply a fourth voltage greater than the third voltage to the third word line in the second stage;
wherein the first word line, the second word line and the third word line are located on a same side of the selected word line.

4. The memory device of claim 3, the peripheral circuit further comprises:
a first voltage generator;
a second voltage generator; and
a control logic coupled to the first voltage generator and the second voltage generator, and configured to:
control the first voltage generator to generate the first voltage, control the second voltage generator to generate the third voltage, apply the first voltage to the first word line and the second word line, and apply the third voltage to the third word line in the first stage; and
control the first voltage generator to generate the second voltage, control the second voltage generator to generate the fourth voltage, apply the second voltage to the first word line and the second word line, and apply the fourth voltage to the third word line in the second stage.

5. The memory device of claim 2, wherein memory cells connected to the first word line, the second word line and the third word line are in an unprogrammed state.

6. The memory device of claim 2, the peripheral circuit is further configured to:
apply a fifth voltage to a fourth word line of the plurality of word lines in the first stage; and
apply a sixth voltage greater than the fifth voltage to the fourth word line in the second stage;
wherein the fourth word line is located on a side of the selected word line different from the side of the selected word line on which the first word line and the second word line are located.

7. The memory device of claim 1, the peripheral circuit is further configured to:
apply a channel boosting voltage to the selected word line in the first stage; and
apply a target programming voltage to the selected word line in the second stage.

8. The memory device of claim 7, wherein
a time instance for applying the target programming voltage is earlier than a time instance for applying the second voltage.

9. The memory device of claim 6, the peripheral circuit is further configured to:
apply a fifth voltage to a fifth word line and a sixth word line of the plurality of word lines in the first stage;
wherein the fifth word line is located on a side of the fourth word line away from the selected word line, and the sixth word line is located on a side of the third word line away from the selected word line.

10. The memory device of claim 6, further comprising: a bit line and a source line;
the programming operation comprises: programming in an order starting from a word line adjacent to the source line to a word line adjacent to the bit line in sequence, or programming in an order starting from a word line adjacent to the bit line to a word line adjacent to the source line in sequence.

11. A memory system, comprising:
a memory device comprising:
a memory cell array;
a plurality of word lines;
a peripheral circuit coupled to the memory cell array through the plurality of word lines, and configured to:
apply a first voltage to a first word line and a second word line of the plurality of word lines in a first stage of a programming operation; and
apply a second voltage greater than the first voltage to the first word line and the second word line in a second stage of the programming operation;
wherein the first word line and the second word line are located on a same side of a selected word line of the plurality of word lines; and
a memory controller coupled to the memory device and configured to control the memory device.

12. A method for operating a memory device, the method comprising:
applying a first voltage to a first word line and a second word line of a plurality of word lines in a first stage of a programming operation; and
applying a second voltage greater than the first voltage to the first word line and the second word line in a second stage of the programming operation;
wherein the first word line and the second word line are located on a same side of a selected word line of the plurality of word lines.

13. The method of claim 12, further comprising:
applying the first voltage to a third word line of the plurality of word lines in the first stage; and
applying the second voltage to the third word line in the second stage;
wherein the first word line, the second word line and the third word line are located on the same side of the selected word line.

14. The method of claim 12, further comprising:
applying a third voltage to a third word line of the plurality of word lines in the first stage; and
applying a fourth voltage greater than the third voltage to the third word line in the second stage;
wherein the first word line, the second word line and the third word line are located on the same side of the selected word line.

15. The method of claim 13, wherein memory cells connected to the first word line, the second word line and the third word line are in an unprogrammed state.

16. The method of claim 13, further comprising:
applying a fifth voltage to a fourth word line of the plurality of word lines in the first stage; and
applying a sixth voltage greater than the fifth voltage to the fourth word line in the second stage;
wherein the fourth word line is located on a side of the selected word line different from the side of the selected word line on which the first word line and the second word line are located.

17. The method of claim 12, further comprising:
applying a channel boosting voltage to the selected word line in the first stage; and
applying a target programming voltage to the selected word line in the second stage.

18. The method of claim 17, wherein a time instance for applying the target programming voltage is earlier than a time instance for applying the second voltage.

19. The method of claim 16, further comprising:
applying a fifth voltage to a fifth word line and a sixth word line of the plurality of word lines in the first stage;
wherein the fifth word line is located on a side of the fourth word line away from the selected word line, and the sixth word line is located on a side of the third word line away from the selected word line.
